(19) United States
(12) Patent Application Publication
(10) Pub. No.: US 2020/0132540 A1
(43) Pub. Date: Apr. 30, 2020

(54) PIEZOELECTRIC ACCELEROMETER

(71) Applicant: TEXAS INSTRUMENTS INCORPORATED, Dallas, TX (US)

(72) Inventors: Scott Robert SUMMERFELT, Garland, TX (US); Mohammad Hadi MOTIEIAN NAJAR, Santa Clara, CA (US); Peter SMEYS, San Jose, CA (US)

(21) Appl. No.: 16/667,507

(22) Filed: Oct. 29, 2019

Related U.S. Application Data
(60) Provisional application No. 62/752,459, filed on Oct. 30, 2018.

(51) Int. Cl. G01H 11/08; G01P 15/18; G01P 15/125; G01P 15/135; H01L 41/113; H01L 41/107; H01L 41/04; H01L 41/047

(52) U.S. Cl. CPC G01H 11/08; G01P 15/18; G01P 15/125; H01L 41/047; H01L 41/1132; H01L 41/107; H01L 41/042; G01P 15/135

(57) ABSTRACT

An acceleration change sensor includes a flexible member comprising extensions extending from a central portion. Piezoelectric capacitors are provided on respective extensions. A proof mass is coupled to the flexible member and offset from each extension of the plurality of extensions.

### CROSS-REFERENCE TO RELATED APPLICATIONS

This application claims priority to U.S. Provisional Application No. 62/752,459, filed Oct. 30, 2018, which is hereby incorporated by reference.

### BACKGROUND

Shock sensors are accelerometers that detect change in acceleration with time. Many types of shock sensors are stand-alone devices that are connected to circuitry external to the sensor. Many shock sensors comprise single-axis accelerometers meaning that they are sensitive to acceleration in only one axis.

### SUMMARY

In one example, an integrated circuit (IC) includes a flexible plate, piezoelectric capacitors, and a proof mass. The flexible plate includes a first pair of arms and a second pair of arms. The first pair of arms is orthogonal to the second pair of arms. The piezoelectric capacitors are on each of the arms of the first pair and on each of the arms of the second pair. The proof mass is coupled to the flexible plate and offset from the first and second pair of arms.

### BRIEF DESCRIPTION OF THE DRAWINGS

FIG. 1 shows a view of an example multi-arm piezoelectric sensor.

FIG. 2 shows a flexible plate with multiple arms usable to form a piezoelectric sensor.

FIG. 3 shows the flexible plate of FIG. 2 flexed to one position by an off-center proof mass attached to the flexible plate.

FIG. 4 shows the flexible plate of FIG. 2 flexed to another position by the off-center proof mass.

FIG. 5 shows a side view of the sensor of FIG. 1.

FIGS. 6A-6C illustrate strain profiles for different arm configurations.

FIG. 7 illustrates a further example of the piezoelectric sensor of FIG. 1.

FIG. 8 shows an example of at least a portion of a method for poling the piezoelectric sensor.

FIGS. 9A-9D illustrate a time sequence of poling actions corresponding to FIG. 8.

FIG. 10 illustrates the hysteresis associated with poling a piezoelectric material.

FIG. 11 shows an example of another portion of a method for poling the piezoelectric sensor.

FIGS. 12A-12D illustrate a time sequence of poling actions corresponding to FIG. 11.

FIG. 13 shows an example of a multi-arm piezoelectric including reference piezoelectric capacitors.

FIG. 14 shows a further example of analog electronics usable to produce a three-axis acceleration signal from the piezoelectric sensor.

### DETAILED DESCRIPTION

The accelerometer change sensor described herein comprises a three-axis piezoelectric sensor. The sensor can be integrated on to a semiconductor die with the circuitry that drives the sensor and processes its output signals. The sensor can be fabricated using micro-electrical mechanical system (MEMS) and wafer level processing to produce a semiconductor device with analog and digital circuitry integrated on the same die as the piezoelectric sensor.

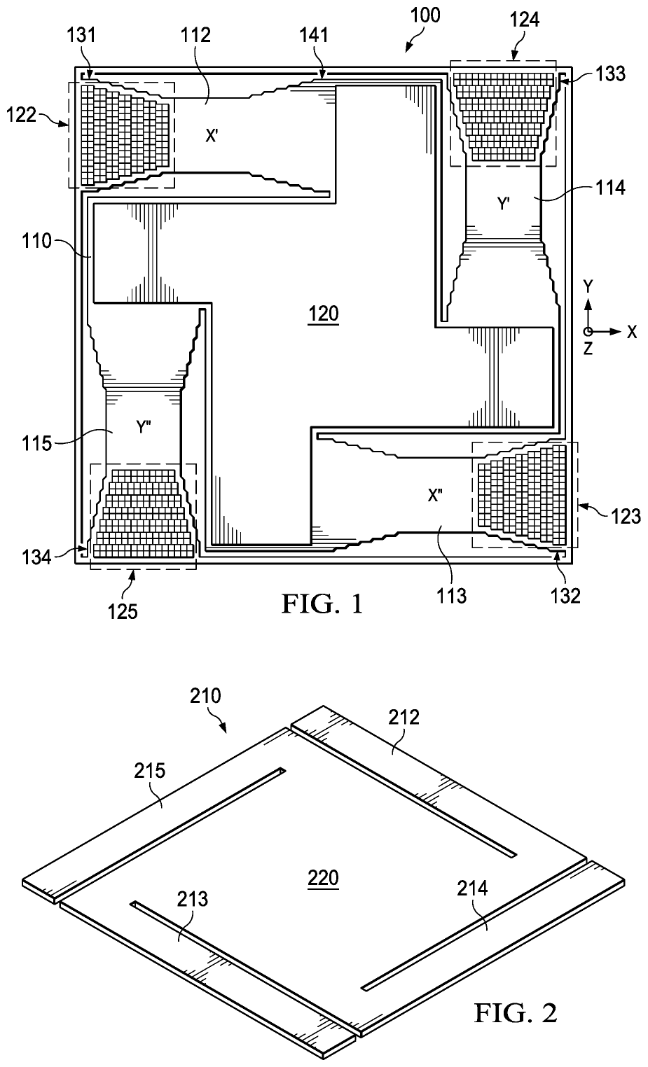

FIG. 1 shows an example of a top-down view of a three-axis piezoelectric sensor 100. The piezo-electric sensor 100 in this example comprises a flexible plate 110 (or other type of flexible member) to which a proof mass 120 is attached (e.g., via adhesive). The flexible plate 110 may be constructed from a dielectric such as silicon dioxide and the proof mass 120 may be constructed from silicon. The flexible plate 110 comprises a central portion to which the proof mass 120 is attached and multiple arms (or other types of extensions) extending from the central portion. In this example, the flexible plate 110 includes four arms 112-115. Arms 112 and 113 are on opposite sides of the flexible plate 110, and similarly arms 114 and 115 are on opposite sides of the flexible plate. Arms 112 and 113 are parallel to each other, as is the case for arms 114 and 115. Arms 112 and 113 are orthogonal to arms 114 and 115. Piezoelectric capacitors (which may have ferroelectric properties) are formed on each arm. Arm 112 includes piezoelectric capacitors 122. Arm 113 includes piezoelectric capacitors 123. Arm 114 includes piezoelectric capacitors 124. Arm 115 includes piezoelectric capacitors 125. As will be explained below, the four arms 112-115 and four sets of piezoelectric capacitors 122-125 permit the piezoelectric sensor 100 to be used as a 3-axis accelerometer change sensor.

The ends of the arms at which the piezoelectric capacitors are formed do not move as the proof mass 120 moves. That is, end 131 of arm 112 remains stationary as force is applied on the opposite end 141 of the arm. Similarly, ends 132, 133, and 134 of arms 113, 114, and 115 remain stationary as the proof mass moves.

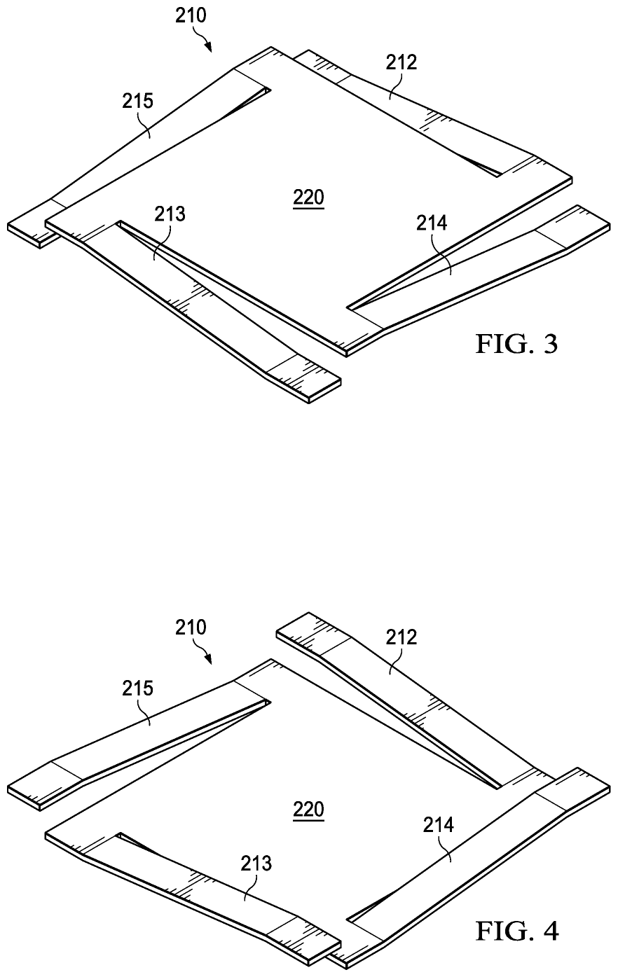

The arms 112-115 in FIG. 1 are shown as being tapered in the middle. FIG. 2 shows an example in which the arms are rectangular. Flexible plate 210 can be used to form the piezoelectric sensor 100 instead of flexible plate 110. Flexible plate 210 includes central portion 220 and four arms 212-215 from therefrom. Arms 212 and 213 are on opposite sides of the flexible plate 210, and similarly arms 214 and 215 are on opposite sides of the flexible plate. Arms 212 and 213 are parallel to each other, as is the case for arms 214 and 215. Arms 212 and 213 are orthogonal to arms 214 and 215. Neither the piezoelectric capacitors on the arms 212-215 nor the proof mass 120 are shown in FIG. 2 so that the flexing of the flexible plate can be illustrated with respect to FIGS. 3 and 4.

As the piezoelectric sensor 100 is subjected to acceleration, the proof mass 120 will move up and down and/or tilt back and forth relative to the arms. FIGS. 3 and 4 illustrate the flexing of the flexible plate 210 as the proof mass (not shown in FIGS. 3 and 4) moves up and down due to acceleration experienced by the sensor. FIG. 3 shows the central portion 220 of the flexible plate 210 as it moves upward relative to the arms 212-215. FIG. 4 shows the central portion 220 of the flexible plate as it moves downward relative to the arms 212-215. The proof mass 120 is positioned offset with respect to the arms 212-215 (or 112-115) and thus causes strain on the arms 212-215 as it moves due to acceleration. The piezoelectric capacitors on each arm thus are also strained and produce electrical signals in proportion to the amount of strain of the respective arm at the location of the piezoelectric capacitors.

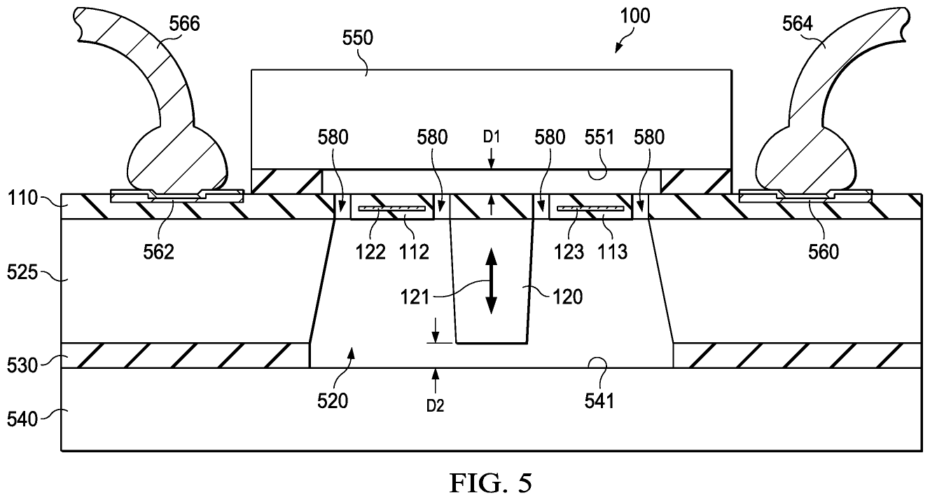

FIG. 5 shows a side view of the piezoelectric sensor 100. Arms 112 and 113 are shown with their respective piezoelectric capacitors 122 and 123. Proof mass 120 shown extending into a cavity 520 formed between the flexible plate 110 and a silicon substrate 540. Layer 530 may comprise silicon dioxide and/or silicon nitride and is formed between the silicon substrate 540 and layer 525. Layer 525 also may comprise silicon and may be formed as a separate wafer from substrate 540. Channels 580 are etched through the silicon dioxide (and/or silicon nitride) of the flexible plate 110 to thereby form the arms.

Cap 550 is formed over the arms of the flexible plate 110 to protect the sensor from external contaminants and damage. Cap 550 may be formed via wafer scale processing as a separate wafer attached to the wafer containing the flexible plate 110 and then etched to form caps 550. Cap 550 and substrate 540 also provide a mechanical stop to prevent excessive vertical excursion (in direction of arrow 121) of the flexible plate 110. Excessive acceleration that would otherwise cause the central portion 220 to flex to the point that it would break is prevented from reaching that level of flexure as either the proof mass 120 will contact surface 541 of substrate 540 or the central portion of the flexible plate 110 will contact surface 551 of the cap 550. FIG. 5 also shows bond wires 564 and 566 connected to corresponding bond pads 560 and 562 of the piezoelectric sensor 100.

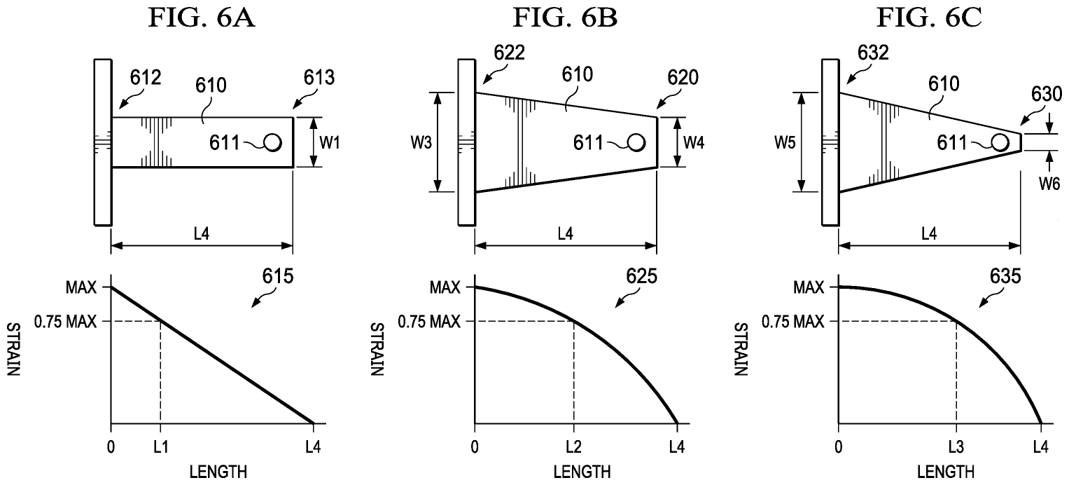

The arms of the flexible plate experience strain due to movement of the proof mass. FIGS. 6a, 6b, and 6c illustrate three different examples of arm geometries and their corresponding strain profiles. The arms shown in FIGS. 6a-6c represent generally half of an arm, that is, the portion of the arm from the outer edge (131, 132, 133, 134) towards its center (which is narrower in the example of FIG. 1). FIG. 6a illustrates a rectangular arm 610 having a length L4 and width W1. The strain profile 615 illustrates the strain experienced along the length of arm 610 as force is applied to the arm at location 611. As shown, the strain profile 615 is linear with respect to distance from left end 612 towards right end 613.

In FIGS. 6b and 6c, the arm portions are trapezoidal. Arm 620 in FIG. 6 has a width W3 on its left end that is larger than its width W4 on its right end. Arm 630 in FIG. 6C also is trapezoidal but the difference between its left-end width W5 and its right-end width W6 is larger than the difference between W3 and W4 of arm 620. Strain profile 625 for arm 620 and strain profile 635 for arm 630 have a similar, non-linear shape. The three strain profiles 615, 625, and 635 show the 75% of strain maximum point. In strain profile 615 for the rectangular arm, the strain is at or above 75% of maximum from the left-end 612 (position 0) to L1. For strain profile 625, the strain is at or above 75% of maximum from the left-end 622 (position 0) to L2, and for strain profile 635 the strain is at or above 75% of maximum from the left-end 622 (position 0) to L3. It is advantageous to place the piezoelectric strain sensor in the region of larger (e.g., maximum) strain.

In the examples of FIGS. 6a-6b, L3 is greater than L2, and L2 is greater than L1. That is, arm 630 has a larger 75% strain area than arm 620, and arm 620 has a larger 75% strain area than arm 610. Larger areas at elevated strain levels may permit more piezoelectric capacitors to be used thereby providing larger signal levels.

As made, the polarization of the domains of the piezoelectric capacitors 122-125 are generally oriented in random directions, which if used as such will result in a relatively small output signal when subject to strain. Before using a piezoelectric as shock sensor, the piezoelectric domains are poled, which involves the application of a voltage across electrodes of the piezoelectric in an attempt to align a larger percentage of the domains in the same direction thereby resulting in a larger signal-to-noise ratio.

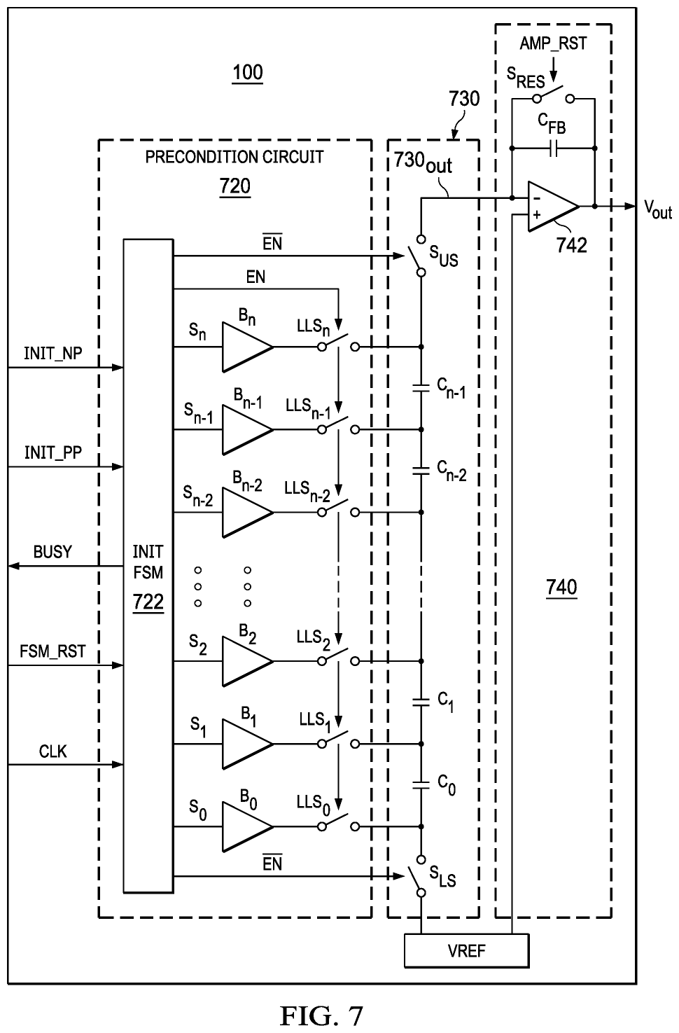

FIGS. 7-12d illustrate an example for poling the piezoelectric capacitors of each the four arms. In this example, piezoelectric sensor 100 includes a precondition circuit 720, piezo capacitor stack 232, a capacitor stack 730, and a sensor output circuit 740. The capacitor stack 730 represents the piezo electric capacitors of a single arm. The precondition circuit 720 may be used to pole the piezoelectric capacitors of the other arms, or a separate precondition circuit may be included and used for each arm's capacitor stack. Further, the sensor output circuit 740 may be shared among the piezoelectric capacitors of the arms, or separate sensor output circuits may be included for each arm. The processing and combination of the output signals from each arm's piezoelectric capacitors to provide a 3-axis shock sensor will be further described below with regard to FIG. 14.

Precondition circuit 720 includes an initialization finite state machine (INIT FSM) 722 in any suitable form, such as comprising logic gates, a controller, and the like. INIT FSM 722 achieves state transitions or sequential operations, as detailed later in connection with communicating n+1 poling signals S₀ through Sₙ ultimately to the piezo capacitor stack 730. In the example shown in FIG. 7, INIT FSM 722 receives four input signals, including a clock signal CLK, a reset signal FSM_RST, a negative polarization signal INIT_NP, and a positive polarization initialization signal INIT_PP. INIT FSM 722 generates poling signals S₀ through Sₙ to the piezo capacitor stack 730. The precondition circuit 720 includes buffers B₀ through Bₙ and low leakage switches LLS₀ through LLSₙ. The output signal from a given buffer B₀ through Bₙ is coupled to a corresponding switch LLS₀ through LLSₙ as shown. The switches LLS₀ through LLSₙ are coupled to the piezo capacitor stack 730. Poling signals S₀ through Sₙ are used to pole the piezo capacitor stack 730. The INIT FSM 722 controls the poling signals. The INIT FSM 722 also generates an enable signal EN (and its complement, E̅N̅) as a switch control as detailed later. Further, INIT FSM 722 generates a BUSY output signal to indicating that the INIT FSM 722 is in an active state (i.e., not in idle state).

Piezo capacitor stack 730 includes a number n of serially-connected capacitors, indicated C₀ through Cₙ₋₁, referred to as a stack to connote the serial connection between successive capacitors, that is, an upper electrode of capacitor C₀ is connected to a lower electrode of capacitor C₁, an upper electrode of capacitor C₁ is connected to a lower electrode of capacitor C₂, and so forth up through an upper electrode of capacitor Cₙ₋₂ being connected to a lower electrode of capacitor Cₙ₋₁. The value of n may be, for example, one or more, and in some instance is in the range of 3 to 64. For connecting poling signals and as described later, the number n of capacitors Cₓ is one less than the number of buffers Bₓ (and low leakage switches LLSₓ).

Concluding the connectivity of the capacitor stack 730, the lower electrode of capacitor C₀ is connected (in addition to switch LLS₀ described above) through a lower stack switch S_{LS} to a reference voltage VREF. The upper electrode of capacitor Cₙ₋₁ is connected (in addition to switch LLSₙ described above) through an upper stack switch S_{US} to an output 730ₒᵤₜ to a corresponding amplifier 742. The stack switches S_{LS} and S_{US} are controlled by a corresponding E̅N̅, that is, when E̅N̅ is asserted, each such switch closes, and when E̅N̅ is de-asserted, each such switch opens.

Sensor output circuit 740 includes a differential amplifier 742. The inverting input of each amplifier 742 is connected to the output 730ₒᵤₜ of the capacitor stack 730. The non-inverting input of amplifier 742 is connected to VREF, which is connected to the lower electrode of capacitor C₀ in each capacitor stack. A feedback capacitor C_{FB} is connected between the output and inverting input of each amplifier 742. The ratio between the sensor stack capacitance and capacitor C_{FB} is essentially a capacitive voltage divider and determines the amplifier gain.

A reset switch, S_{RES}, is connected in parallel with feedback capacitor C_{FB}, whereby switch S_{RES} is operable to close in response to a signal AMP_RST for purposes of defining a direct current (DC) bias point by asserting AMP_RST, initializing 730ₒᵤₜ, and then de-asserting AMP_RST after which alternating current (AC) voltage is properly divided as between C_{FB} and the capacitor stack 730. In this regard, therefore, switch S_{RES} allows for compensation in that the amplifier 742 does not have resistive feedback, so any charge accumulation across capacitor C_{FB} (due to leakage of any source) can cause the amplifier's output voltage to drift. Accordingly, AMP_RST can be asserted: (i) before sensing mode starts; (ii) periodically to mitigate drift; or (iii) when large vₒᵤₜ offset is observed, where the last two scenarios also apply to temperature changes.

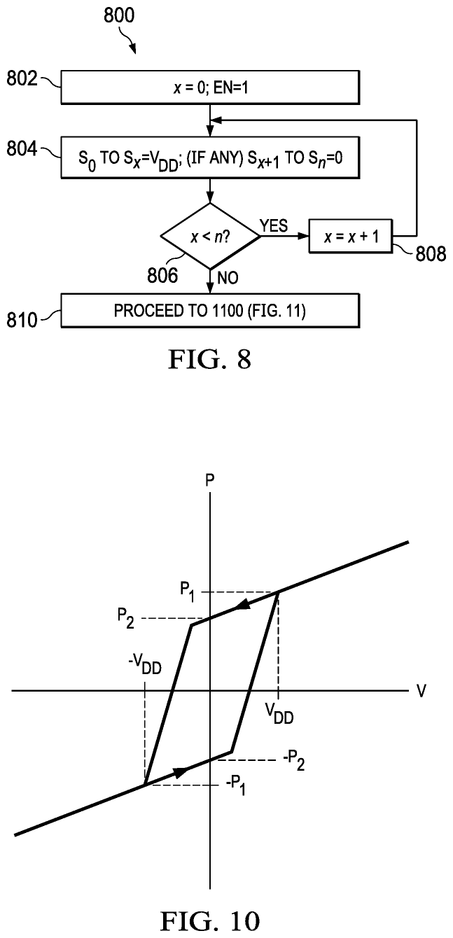

The piezo capacitor stack 730 is poled from time-to-time (e.g., at system start-up, at fixed time intervals during operation of the sensor 100, etc.). FIGS. 8-12D illustrate a method 800 that may be used to pole capacitor stacks 730. Method 800, implemented by INIT FSM 722, commences at 802, in which an index x is established so as to facilitate looping through a total of n+1 iterations of a sequence, as controlled in part by index x. Also, during this iteration, as established for example at 802, EN=1, thereby closing all of the low leakage switches LLS₀ through LLSₙ, so that poling signals S₀ through Sₙ are connected to respective nodes in capacitor stack 232, 234. Note that with EN=1, its complement is E̅N̅=0, thereby opening switches S_{US} and S_{LS}, and isolating capacitor stack 730 from sensor output circuit 740.

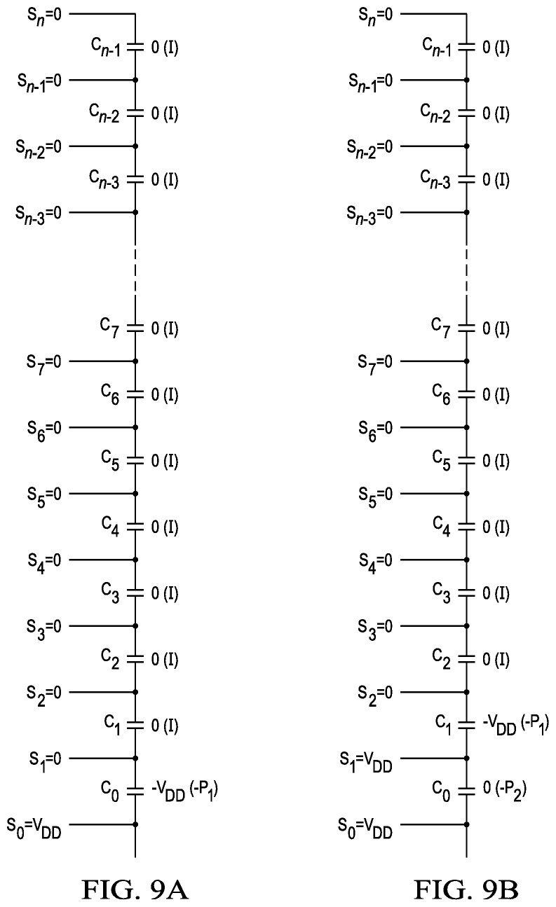

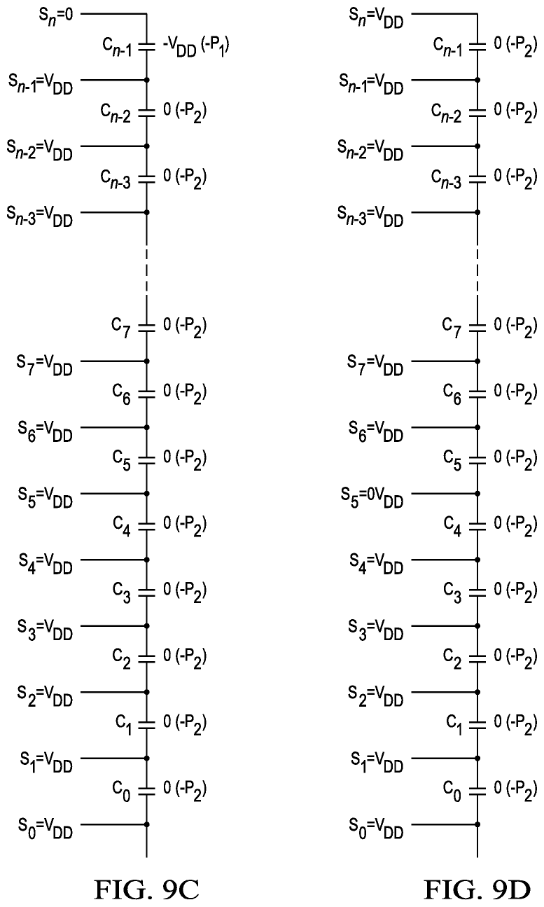

After initializing the index value, at 804 a first subset of poling signals S₀ through Sₙ, namely, S₀ to Sₓ, are set to V_{DD}, while a second subset of poling signals, namely, the remaining Sₓ₊₁ to Sₙ, are set to ground (shown as zero volts). By way of example, therefore, for the first iteration of operation 804 (i.e., x=0 from operation 802), then the first subset of signals has S₀=V_{DD}, while the second and remaining poling signals S₁ through Sₙ all equal 0. To further illustrate this example, FIG. 9A illustrates a simplified and partial view of a capacitor stack, with the application of the first iteration of these signals as described. Thus, with S₀=V_{DD} and S₁=0, note that the voltage across capacitor C₀ is ˜V_{DD}, as shown to the right of the capacitor in FIG. 9A. At the same time, however, with the remaining Sₓ₊₁ to Sₙ equal to ground, then each of the other capacitors C₁, . . . , Cₙ₋₁ has a voltage of 0 volts across it, as also shown to the right of each of those capacitors.

Additionally, in FIG. 9A, a parenthetical is shown to the right of the voltage across each capacitor. A piezoelectric material will polarize in response to energy (e.g., voltage) applied to it, and the general nature of the response curve demonstrating such polarization is shown by way of example in FIG. 10, which is not drawn to scale but generally depicts a hysteresis aspect. Specifically, FIG. 10 illustrates voltage (V) along its horizontal axis and material polarization (P) along its vertical axis. With hysteresis, however, the piezoelectric polarization at 0 volts depends on the direction of the voltage as it approached the 0 volt point, namely, for a voltage that was negative and increases toward 0 volts, then at 0 volts the ferroelectric polarization is at a level shown as −P₂, whereas for a voltage that was positive and decreases toward 0 volts, then at 0 volts the ferroelectric polarization is at a level shown as P₂. Note that FIG. 10 is drawn symmetrically for sake of simplifying the illustration, discussion, and understanding, so that −P₂ has the same magnitude as P₂. Due to the fabrication sequence, however, the absolute values of positive and negative polarization magnitudes may differ from each other when a capacitor is subjected to either V_{DD} or −V_{DD}.

Referring back to FIG. 9A, therefore, for the first instance of operation 802 from method 800, the voltage across capacitor C₀ is −V_{DD}, so the polarization across that device is −P₁. Note for sake of reference that capacitors C₁, . . . Cₙ₋₁, that is, that the capacitors above capacitor C₀ in stack 730, will not yet have been intentionally polarized in response to a voltage signal and therefore the parenthetical indication of “I” shown in FIG. 9A (and later figures) is intended to indicate an indeterminate state.

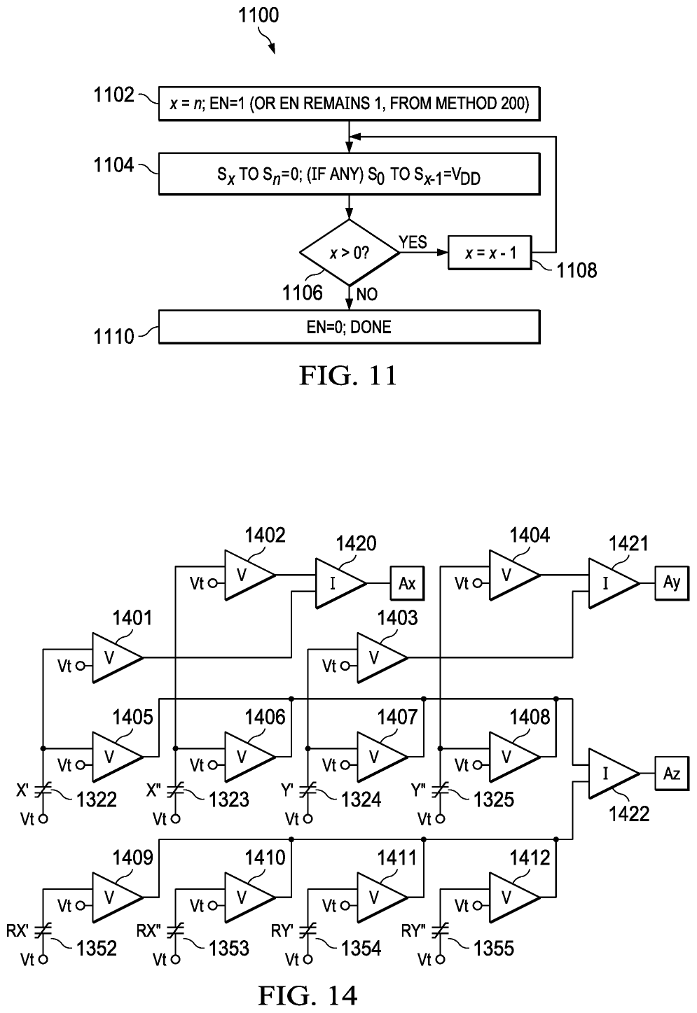

At 806 in FIG. 8, the method includes comparing the loop index x to determine if it is less than (i.e., has not completed) all of the n+1 of poling signals S₀ through Sₙ. If the loop index x is less than n, then method 800 proceeds to step 808, which increments the loop index x and returns flow to 804. However, if the loop index x is no longer less than n, then method 800 proceeds to 810 to complete the method, which also as shown can then transition to method 1100 of FIG. 11, detailed below.

For each increase in loop index x in FIG. 8, then one at a time, from the bottom of stack upward, each successive capacitor Cₓ will receive a voltage of ground at its upper electrode, with a voltage of V_{DD} at its lower electrode, thereby causing the capacitor, in response to those respective voltages, to attain a polarization of −P₁. In addition, however, note now the additional operation once the loop index x equals one or more. Specifically, FIG. 9B illustrates the biasing signals and polarization of capacitor stack 730 when the loop index x equals one. Per operation 804, therefore, the first subset of poling signals is S₀ through S₁ and equal V_{DD}, while the second subset of poling signals is S₂ through Sₙ, and equal zero volts. Again, therefore, the capacitor Cₓ, which for x equals 1, is C₁, receives ground at its upper electrode and V_{DD} at its lower electrode, polarizing the capacitor at −P₁; note, however, the effect of the loop on the capacitor immediately below capacitor Cₓ in the serial path, that is, at capacitor Cₓ₋₁, which in the current example is capacitor C₀. For that capacitor, both its upper and lower electrodes are now at V_{DD}, so the voltage across the capacitor, formerly at −V_{DD} for the immediately preceding iteration of x=x−1, is now switched to 0 volts. According to the hysteresis response of FIG. 10, therefore, the polarization across the capacitor will recede in magnitude, but not change polarity, from −P₁ to −P₂. Hence, for the iteration of method 800 when x=1, the polarization of capacitor C₀ is −P₂, while the polarization of capacitor C₁ is −P₁.

For each successive loop iteration x of method 800, one additional capacitor at a time (e.g., per CLK of INIT FSM 722 of FIG. 7), compared to the immediately preceding iteration x−1, will achieve a polarization of −P₁, with each capacitor below that additional capacitor having achieved a polarization of −P₂. FIG. 9C, by way of example, therefore illustrates the loop iteration for x=n−1, in which case all poling signals in a first subset from S₀ to Sₙ₋₁ equal V_{DD}, while the remaining poling signal in the second subset, namely Sₙ, equals 0. Thus, following those n−1 loop iterations, all capacitors C₀ through Cₙ₋₂ will be polarized to −P₂, while capacitor Cₙ₋₁ will be polarized to −P₁. Further, for the iteration of x=n−1, then operation 806 is still satisfied, so operation 808 is repeated one more time to increment x=n and step 804 is repeated, with the result being that illustrated in FIG. 9D. Specifically, in this final loop iteration of method 800, wherein x=n, then all poling signals in a first subset from S₀ to Sₙ equal V_{DD}, while the remaining subset is the null set, as there are no additional poling signals having an index greater than n. Further, therefore, in this iteration for x=n, Sₙ=V_{DD}, whereas in the immediately preceding iteration of x=n−1 then Sₙ=0, so whereas capacitor Cₙ₋₁ was polarized to −P₁ for the iteration of x=n−1 in response to a voltage across it of −V_{DD}, when x=n then the voltage of Sₙ=Sₙ₋₁=V_{DD} increases the voltage across capacitor Cₙ₋₁ from −V_{DD} to zero, thereby causing it to polarize, as indicated by the response curve in FIG. 10, to a polarization of −P₂. Thus, for x=n, capacitor Cₙ₋₁ remains negatively polarized, and is now polarized in a same direction and same magnitude as all other capacitors in stack 730.

As described above, method 800 commences with 0 volts across each capacitor in the capacitor stack, and then from a direction in ascending index x for capacitor Cₓ in the capacitors C₀ up to Cₙ₋₁, then one capacitor a time and for that index is biased to a first polarity having a first magnitude and a first direction, and then in a successive ascension of the index to x+1 that same capacitor is further biased to maintain that same first polarity direction, albeit changing, potentially, by some difference in magnitude. Given that the sequence of such changing biases may be perceived as from the bottom of the stack (i.e., as to capacitor C₀, closest to VREF), in an upward direction in the schematic sense of stack 730 (i.e., toward capacitor Cₙ₋₁, the top electrode of which is the stack output vₒᵤₜ), then the process may be perceived as akin to an upward zipper of values, where each ascendant step of the zipper is the new application of V_{DD} to a next selected capacitor upper electrode in the serial chain, thereby moving that capacitor to a negative polarity while ensuring the capacitor(s) below the selected capacitor also maintain(s) a likewise, and earlier established, negative polarity. Accordingly, as the figurative zipper moves up, the magnitude of the polarization across each capacitor may recede, but it will not change state (i.e., from negative to positive or vice versa) by virtue of the sequencing of the preferred embodiment. As a result, upon completion of method 500, all capacitors in the stack have co-aligned directionality of polarization.

Having described a bottom-upward, negative polarization technique for capacitor stack 730, an embodiment also includes a defined sequence to prevent random events, such as the possibility of a change in polarity direction, while removing the non-zero biases applied by poling signals S₀ through Sₙ to the capacitor stack. In this regard, FIG. 11 illustrates an example method 1100 that may be used in sequentially removing the non-zero poling signals in a controlled and defined manner, so as to reduce or eliminate issues that may arise from otherwise uncontrolled discharge events.

Method 1100 commences at 1102, in which the loop index x is initialized to n, that is, the number of the topmost poling signal Sₙ, again to facilitate a sequential looping through a total of n+1 iterations for the n+1 poling signals, but here in a decrementing fashion so as to sequence from the top of capacitor stack 730 downward. Meanwhile, again for operation 1102 (as was the case for method 800 of FIG. 8), EN=1, thereby closing all of the low leakage switches LLS₀ through LLSₙ, so that poling signals S₀ through Sₙ are connected to respective nodes in the capacitor stack (and E̅N̅=0 keeps switches S_{US} and S_{LS} open).

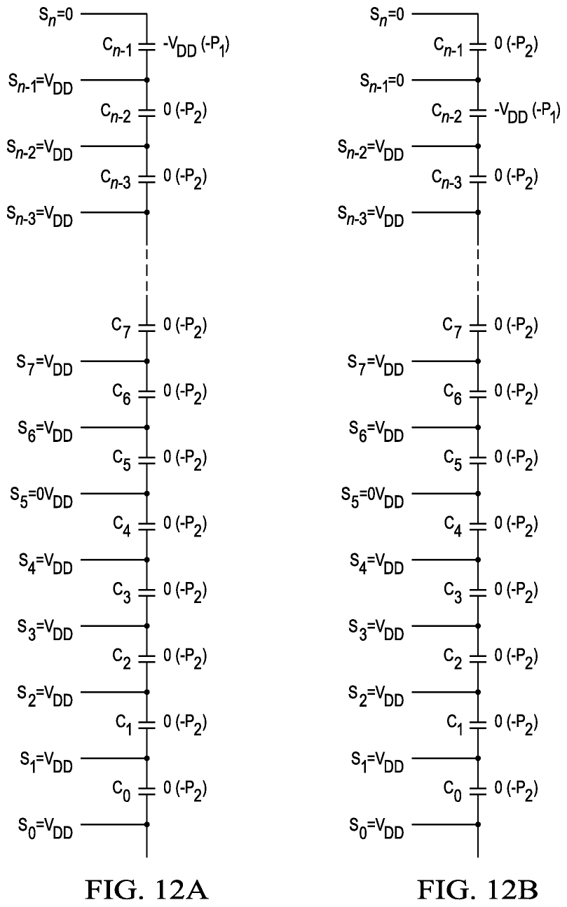

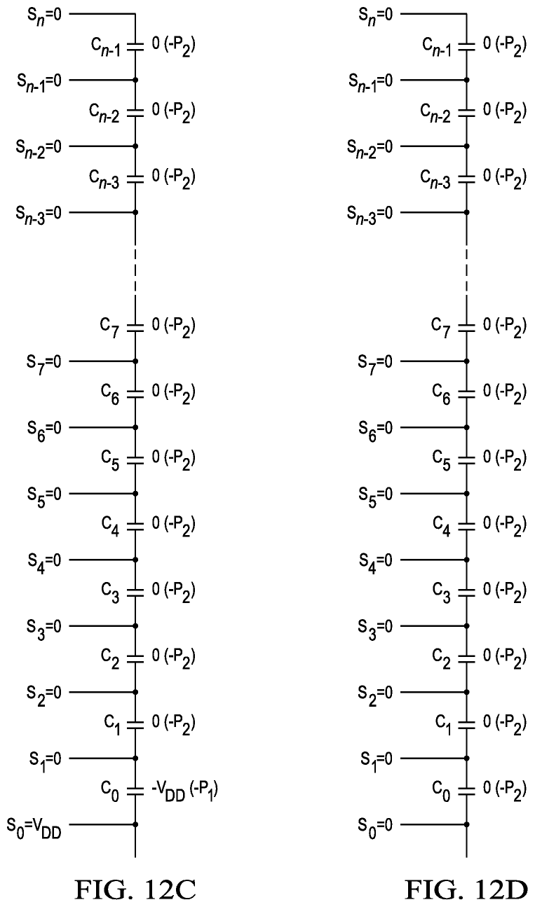

At 1104, a first subset of the poling signals S₀ through Sₙ, namely, S₀ to Sₓ₋₁, are set to V_{DD} (or maintained at V_{DD} from method 800) while a second subset of the poling signals Sₓ through Sₙ, being the remaining poling signals not included in the first subset and, therefore, Sₓ to Sₙ, are set to ground (shown as zero volts). By way of example, therefore, for the first iteration of 1104 (i.e., x=n from step 1102), then the first subset of signals has S₀ through Sₙ₋₁ equal to V_{DD}, while the second subset and remaining poling signal Sₙ equals 0. To further illustrate this example, FIG. 12A again illustrates the simplified and partial view of the capacitor stack as used in FIGS. 9A through 9D, but here with the application of poling signals from method 1100. Thus, in FIG. 12A, with Sₙ=0 and Sₙ₋₁=V_{DD}, the voltage across capacitor Cₙ₋₁ is −V_{DD}, as shown to the right of the capacitor in FIG. 12A. At the same time, however, with the remaining S₀ to Sₓ₋₁ equal to V_{DD}, then each of the other capacitors C₀, . . . , Cₙ₋₂ has a voltage of 0 volts across it, as also shown to the right of each of those capacitors. Additionally, in FIG. 12A, to the right of the voltage across each capacitor is again shown a parenthetical with the resultant polarization. Accordingly, from the first instance of operation 1104, the voltage of −V_{DD} across capacitor Cₙ₋₁ results in a ferroelectric material polarization of −P₁. For the remaining capacitors C₀, . . . Cₙ₋₂, that is, that the capacitors below capacitor Cₙ₋₁ in the capacitor stack, those capacitors will have been formerly polarized to −P₂ by the earlier application of method 800 and therefore the parenthetical indication of “−P₂” is shown in FIG. 12A (and later figures, where applicable).

Method 1100 continues to at operation 1106, which compares the loop index x to see if it has reached zero, that is, in effect determining whether the bottommost poling signals Sₙ has been processed in the loop. If the loop index x is greater than zero, then method 1100 proceeds to operation 1108 which decrements the loop index x and returns flow to step 1104, whereas if the loop index x reaches (i.e., is equal to) zero, then method 1100 proceeds to operation 1110 in which EN is set to zero so as to complete the method and whereby its complement thereby closes switches S_{US} and S_{LS}.

For each decrease in loop index x, then from the top of the capacitor stack downward, each successive capacitor Cₓ will receive a voltage of 0 at its upper electrode, with a voltage of V_{DD} at its lower electrode, thereby causing the capacitor, in response to those respective voltages, and the −V_{DD} difference between them, to achieve a polarization of −P₁. FIG. 12B illustrates the biasing signals and polarization of the capacitor stack when the method 1100 loop index x equals n−1. Thus, Sₙ₋₁ equals 0 at the upper electrode of capacitor Cₙ₋₂, while Sₓ₋₁ (i.e., S₍ₙ₋₁₎₋₁=Sₙ₋₂) equals V_{DD} at the bottom electrode of capacitor Cₙ₋₂, polarizing the capacitor at −P₁. Note, however, the effect of the loop on the capacitor above capacitor Cₙ₋₂, that is, at capacitor Cₙ₋₁. For that capacitor, both its upper and lower electrodes are now at 0 volts, so the voltage across the capacitor, formerly at −V_{DD} for the immediately preceding iteration of x=n, is now switched to 0 volts. Hence, per FIG. 10 the polarity direction of the capacitor does not change, while the polarization magnitude of the capacitor changes from −P₁ to −P₂. FIG. 12C illustrates the biasing signals and polarization of the capacitor stack when the method 800 loop index x equals 1, and FIG. 12D illustrates the biasing signals and polarization of the capacitor stack when the method 800 loop index x equals 0. By the last step as illustrated in FIG. 9D, each capacitor, formerly having a polarization of −P₁ for one cycle wherein there is −V_{DD} across it, has for a next loop then had 0 volts applied across both its upper and lower electrodes, thereby changing the polarization from −P₁ to −P₂, in an orderly, sequential and controlled fashion, so as to discharge the signal applied to the device while ensuring the polarization remains negative and, therefore, does not switch state to a positive polarization.

From the above, method 800 essentially achieves a uniform negative polarization of −P₂ across each capacitor in the capacitor stack 730 (see FIG. 9D), by sequentially polarizing each successive capacitor in a first direction (e.g., bottom upward) across the capacitor stack, and method 1100 controllably preserves that negative polarization of −P₂ across each capacitor in the capacitor stack (see FIG. 12D), by sequentially discharging both capacitor electrodes to ground for each successive capacitor in a second direction (e.g., top downward), opposite the first direction. Following poling of the piezoelectric capacitors of the sensor 100, the sensor can be used as a 3-axis shock detector.

Referring again to FIG. 1, an XYZ coordinate system is shown. The piezoelectric capacitors 122, 123 of arms 112, 113 are sensitive to strain imposed on the proof mass 120 along the X axis, and capacitors 124, 125 of arms 114, 115 are sensitive to strain imposed on the proof mass 120 along the Y axis. The signal produced by the piezoelectric capacitors 122 of arm 112 is designated X′. The signal produced by the piezoelectric capacitors 123 of arm 113 is designated X″. Similarly, the signals produced by the piezoelectric capacitors 124, 125 of Y-axis arms 114 and 115 are designated Y′ and Y″, respectively. Strain along the Z-axis can be calculated based on the X′, X″, Y′, and Y″ signals. In one implementation, changes in accelerations in the X and Y directions, respectively, are calculated as X=X′−X″ and Y=Y′−Y″. From a circuit standpoint this subtraction can be accomplished by combining the two signals in a differential operational amplifier. In this manner, changes in these signals from the changes in the strain create output the signal. The changes in acceleration in the Z direction is determined as the sum of the four X and Y signals, that is, Z=X′+X″+Y′+Y″.

The material used for the piezoelectric capacitors may comprise lead zirconate titanate (PZT) which may have a substantial pyroelectric property. A pyroelectric property means that the material is sensitive to changes in temperature. As, such the piezoelectric sensor 100 may not be able to differentiate changes in temperature from changes in mechanical strain.

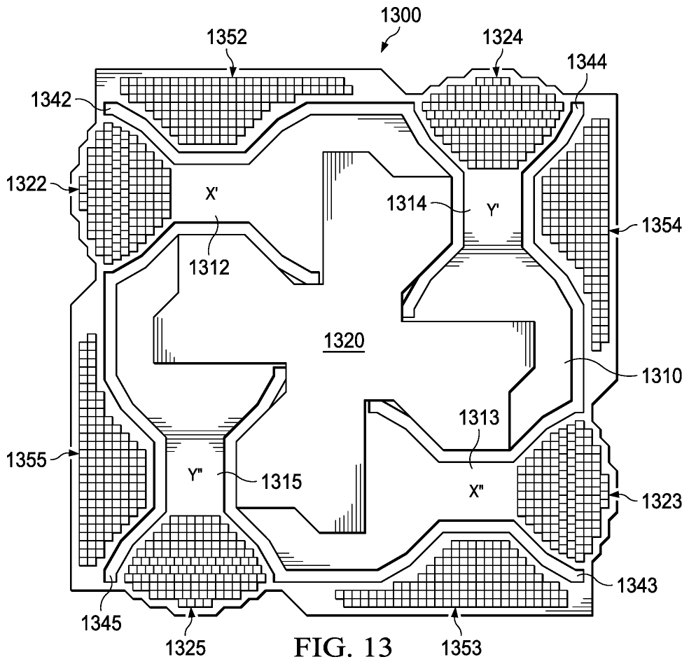

FIG. 13 shows an example implementation of a piezoelectric sensor 1300 having a similar configuration to that shown in FIG. 1, but also have a reference capacitor near each of the main piezoelectric capacitors that share the same temperature environment as the sense capacitors yet have little strain due to changes in acceleration on the proof mass. In the example of FIG. 13, the sensor 1300 includes a flexible plate 1310, such as that described above, to which a proof mass 1320 is attached. Four arms 1312, 1313, 1314, and 1315 extend from the flexible plate 1310 as described above. The arms 1312-315 in this example can have any of the shapes described above (e.g., tapered in the middle as shown in FIG. 13, rectangular, trapezoidal, etc.). Piezoelectric capacitors 1322, 1323, 1324, and 1325 are provided on the arms 1312-1315 as shown.

Reference capacitors 1352, 1353, 1354, and 1355 are shown near respective piezoelectric capacitors 1322-1325. Reference capacitors 1352-1355 may be made from the same material as piezoelectric capacitors 1322-1325 (e.g., lead zirconate titanate). As such, the effect of temperature on piezoelectric capacitors 1323-1325 (which sense strain) is the same as on the reference capacitors 1352-1355. Although formed on the same layer of material (e.g., silicon dioxide) comprising flexible plate 1310, reference capacitors 1352-1355 are mechanically isolated from capacitors 1322-1325 by etching the silicon dioxide between the sets of capacitors. Reference capacitor 1352 is mechanically from corresponding piezoelectric capacitor 1322 by trench 1342 etched through the silicon dioxide layer. Similarly, reference capacitor 1353 is mechanically isolated from corresponding piezoelectric capacitor 1323 by trench 1343. Reference capacitor 1354 is mechanically from corresponding piezoelectric capacitor 1324 by trench 1344, and reference capacitor 1355 is mechanically from corresponding piezoelectric capacitor 1325 by trench 1345. As such, reference capacitors 1352-1355 are not subjected to the strain to which the piezoelectric capacitors 1322-1325 are subjected by movement of the proof mass 1320. The reference capacitors 1352-1355 have the same temperature coefficient as the main sense piezoelectric capacitors 1323-1325 but are mechanically isolated form the piezoelectric capacitors.

The effect of temperature can be removed from the X, Y, and Z acceleration signals as follows. Accelerations in the X and Y directions, respectively, are calculated as X=X′−RX′−X+RX″ and Y=Y′−RY′−Y″−RY″, where RX′ is the signal from the reference capacitor 1352, RX″ is the signal from the reference capacitor 1353, RY′ is the signal from the reference capacitor 1354, and RY″ is the signal from the reference capacitor 1355. Since the temperature changes of X′ and X″ are the same and the temperature changes of Y′ and Y″ are the same, the acceleration change can be calculated for the X direction as X=X′−X″ and Y=Y′−Y″ without using signals from the reference capacitors. The acceleration in the Z direction is determined as the sum of the four X and Y signals minus the sum of the corresponding reference capacitor signals, that is, Z=X′+X″+Y′+Y′−′RX′−RX″−RY′−RY′. The reference capacitors are useful for the determination of the Z direction acceleration change because the sense capacitors X′, X″, Y′, and Y″ are all added or combined. The reference capacitors are needed to provide the temperature compensation.

FIG. 14 shows example implementation of analog circuitry used to generate the acceleration signals on all three axes X, Y, and Z. This example includes voltage amplifiers 1401-1412 and current amplifiers 1420-1422. The output form current amplifier 1420 is shown as signal Ax (the x-axis component of the acceleration change signal). Similarly, the outputs from current amplifiers 1421 and 1422 are shown as the corresponding y and z-axis components—Ay and Az. One input of each of the voltage amplifiers 1401-1412 is coupled to a threshold voltage Vt. The piezoelectric capacitor 1322 is coupled to input terminals of voltage amplifiers 1401 and 1405. Similarly, piezoelectric capacitor 1323 is coupled to respective input terminals of voltage amplifiers 1402 and 1406. Piezoelectric capacitor 1324 is coupled to respective input terminals of voltage amplifiers 1403 and 1407. Piezoelectric capacitor 1325 is coupled to respective input terminals of voltage amplifiers 1404 and 1407. Reference capacitors 1352, 1353, 1354, and 1355 are coupled to respective input terminals of voltage amplifiers 1409, 1410, 1411, and 1412.

The outputs of the voltage amplifiers 1409-1412 are coupled together (to thereby add together the signals from the reference capacitors 1352-1355) and to an input of current amplifier 1422. Similarly, the outputs of the voltage amplifiers 1405-1408 are coupled together (to thereby add together the signals from the main sense piezoelectric capacitors 1322-1325) and to another input of current amplifier 1422, to thereby generate the Az signal.

The outputs of voltage amplifiers 1401 (which provides the X′ signal) and 1402 (which provides the X″ signal) are coupled to respective inputs of current amplifier 1420 to thereby generate the Ax signal (X′-X″). Similarly, the outputs of voltage amplifiers 1403 (which provides the Y′ signal) and 1404 (which provides the Y″ signal) are coupled to respective inputs of current amplifier 1421 to thereby generate the Ay signal (Y′-Y″).

In this description, the term “couple” or “couples” means either an indirect or direct wired or wireless connection. Thus, if a first device couples to a second device, that connection may be through a direct connection or through an indirect connection via other devices and connections. The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. An integrated circuit (IC), comprising:
a flexible plate comprising a first pair of arms and a second pair of arms, the first pair orthogonal to the second pair;
piezoelectric capacitors on each of respective arms of the first pair and on each of the arms of the second pair; and
a proof mass coupled to the flexible plate and offset from the first and second pair of arms.

2. The IC of claim 1, wherein each arm of the first and second pair of arms is trapezoidal from an outside edge of the arm towards a center of the arm.

3. The IC of claim 1, wherein the arms of the first pair of arms have opposing ends and are tapered between the opposing ends.

4. The IC of claim 1, wherein the proof mass comprises silicon.

5. The IC of claim 1, wherein the arms of the first pair are parallel to each other, and the arms of the second pair are parallel to each other.

6. The IC of claim 1, wherein the proof mass resides at least partially within a cavity of the IC, and the IC further includes a cap on a side of the flexible plate opposite the proof mass.

7. The IC of claim 1, further comprising reference piezoelectric capacitors, wherein the piezoelectric capacitors on the arms are subject to strain as the proof mass moves due to acceleration, but the reference capacitors are arranged so as not to be subject to the strain.

8. The IC of claim 1, further comprising pre-amplifiers coupled to the piezoelectric capacitors, the pre-amplifiers configured to provide a three-axis measurement of changes in acceleration.

9. The IC of claim 1, wherein the flexible plate comprises silicon dioxide.

10. An acceleration change sensor, comprising:
a flexible member comprising first and second extensions extending from a central portion;
piezoelectric capacitors on each of the first and second extensions of the plurality of extensions; and
a proof mass coupled to the flexible member and offset from each of the first and second extensions.

11. The acceleration change sensor of claim 10, wherein the flexible member comprises at least one of silicon dioxide or silicon nitride and the proof mass comprises silicon.

12. The acceleration change sensor of claim 10, wherein the flexible member comprises four extensions.

13. The acceleration change sensor of claim 12, wherein:
the four extensions comprise the first and extensions as well as third and fourth extensions;
the first and second extensions are parallel to each other; and
the third and fourth extensions are parallel to each other.

14. The acceleration change sensor of claim 13, wherein the first and second extensions are orthogonal to the third and fourth extensions.

15. The acceleration change sensor of claim 10, wherein each extension of the four extensions is trapezoidal from an edge towards a center of the extension.

16. The acceleration change sensor of claim 10, wherein each extension of the four extensions has opposing ends and is tapered between the opposing ends.

17. An integrated circuit (IC), comprising:
a flexible plate comprising a first pair of arms and a second pair of arms, the first pair orthogonal to the second pair;
piezoelectric capacitors on each of the arms of the first pair and on each of the arms of the second pair;
a proof mass coupled to the flexible plate and offset from the first and second pair of arms, the proof mass at least partially residing within a cavity; and
a cap on a side of the flexible plate opposite the proof mass;
wherein the piezoelectric capacitors are configured to be subject to strain upon movement of the proof mass within the cavity.

18. The IC of claim 17, wherein the arms of the first pair of arms have opposing ends and are tapered between the opposing ends.

19. The IC of claim 17, further comprising reference piezoelectric capacitors, wherein the reference capacitors are arranged so as not to be subject to the strain upon movement of the proof mass.

20. The IC of claim 17, wherein the flexible plate comprises silicon dioxide and the proof mass comprises silicon.
